(19) United States
(12) Patent Application Publication
(10) Pub. No.: US 2007/0258293 A1
(43) Pub. Date: Nov. 8, 2007

(54) Data output circuit for semiconductor memory apparatus

(75) Inventor: Hyung Dong Lee, Gyeonggi-do (KR)

Correspondence Address: VENABLE LLP, P.O. BOX 34385, WASHINGTON, DC, 20043-9998, US

(73) Assignee: Hynix Semiconductor Inc., Gyeonggi-do (KR)

(21) Appl. No.: 11/647,478

(22) Filed: Dec. 29, 2006

(30) Foreign Application Priority Data
May 8, 2006 (KR) 10-2006-0040932

(51) Int. Cl. G11C 7/10; G11C 7/00

(52) U.S. Cl. 365/189.06; 365/193

(57) ABSTRACT

A plurality of first drivers outputs a plurality of data based on first control signals. A second driving unit generates a second control signal synchronized with data output cycles of the first drivers using the first control signals. An amplitude correcting unit corrects an amplitude of the second control signal using at least the first control signals.

### BACKGROUND

The following relates to a semiconductor memory apparatus, in particular, to a data output circuit for a semiconductor memory apparatus.

Generally, systems such as a semiconductor memory apparatus, a chip set or a processor that uses the semiconductor memory apparatus typically use a predetermined clock in order to input/output data to/from the semiconductor memory apparatus or a clock supplied from the semiconductor memory apparatus. The clock supplied from the semiconductor memory apparatus is a strobe clock DQS that is generated to synchronize with data input/output to/from the semiconductor memory apparatus.

A data output circuit of the semiconductor memory apparatus typically includes a data driver 10 and a DQS driver 20, as shown in FIG. 1.

The data driver 10 receives a plurality of data Data_in that are read out from a plurality of cells and correspond to address input and drives the data according to a rising clock RCLK, a falling clock FCLK, and an output control signal OE. The rising clock RCLK and the falling clock FCLK are generated from a clock distribution Circuit. The rising clock RCLK is synchronized with a rising edge of an external clock. The falling clock FCLK is synchronized with a falling edge of the external clock.

The DQS driver 20 receives the rising clock RCLK, the falling clock FCLK, and the output control signal OE to output the strobe clock DQS to read out the data Data_out output from the data driver 10 at a time synchronized with the data output cycle of the semiconductor memory apparatus in a system, for example, a chip set or a processor to which the data Data_out is input.

A system to which the semiconductor memory apparatus is applied recognizes that the data is output from the semiconductor memory apparatus using the strobe clock DQS and reads out the data Data_out.

Typically, the data driver 10 is designed to have fixed impedance regardless of the shifting of the data Data_out.

If the data Data_out is regularly shifted, there is no problem, since the data is not regularly shifted.

However, typically the impedance of the DQS driver 20 is equal to the impedance of the data driver 10. The amplitudes of the data Data_out and the strobe clock DQS are different from each other due to the difference in loading amounts, as shown in FIG. 2. That is, the amplitude of the strobe clock DQS is smaller than the data Data_out.

Further, if a system has a large output load, reference points for recognizing the data Data_out and the strobe clock DQS are distributed differently from each other. Thus, the skews of the data Data_out and the strobe clock DQS are increased.

Accordingly, the amplitude of the strobe clock DQS is smaller than that of the data Data_out, and the input margin of the system to which the data Data_out is supplied is reduced due to the increased skews of the data Data_out and the strobe clock DQS. As a result, the performance of the entire system is degraded. Further, when the operational frequency of the system is increased, the above problem might become more serious, which is unacceptable in high speed systems.

### SUMMARY

An exemplary embodiment provides a data output circuit and a method for a semiconductor memory apparatus that increases amplitude of a synchronization clock while minimizing the skew of the output data and the synchronization clock.

An exemplary embodiment includes a plurality of first drivers that output a plurality of data based on first control signals; a second driver that generates and outputs a second control signal synchronized with data output cycles of the first driving unit using at least the first control signals; and an amplitude correcting unit that corrects an amplitude of the second control signal using at least the first control signals.

An exemplary embodiment includes a plurality of first data drivers that output a plurality of data based on first control signals; a second driver that generates and outputs a second control signal synchronized with data output cycles of the first drivers using timing corrected first control signals; an amplitude correcting unit that corrects an amplitude of the second control signal using the timing corrected first control signals; and a timing correcting unit that modifies the timing of the first control signals for a predetermined time and outputs the timing corrected first control signals.

### BRIEF DESCRIPTION OF THE DRAWINGS

FIG. 1 is a block diagram showing the structure of a data output circuit of semiconductor memory apparatus according to the related art.

FIG. 2 is an output waveform view of the data output circuit of the semiconductor memory apparatus according to the related art.

FIG. 3 is a block diagram showing an exemplary data output circuit of a semiconductor memory apparatus according to an exemplary embodiment.

FIG. 4 is a circuit diagram showing an exemplary data driver of the data output circuit of FIG. 3.

FIG. 5 is a circuit diagram showing an exemplary DQS driver of the data output circuit of FIG. 3.

FIG. 6 is a block diagram showing an exemplary timing correcting unit of the data output circuit of FIG. 3.

FIG. 7 is an output waveform view of an exemplary data output circuit according to an exemplary embodiment.

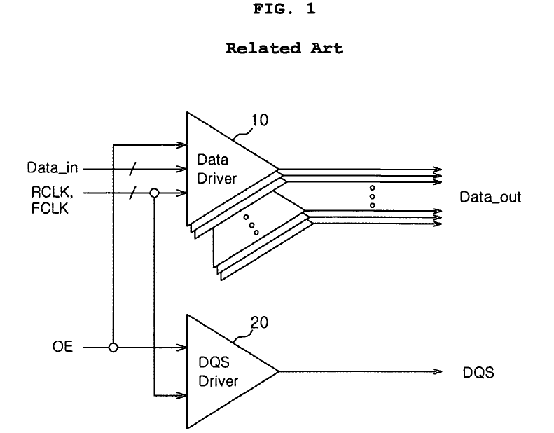

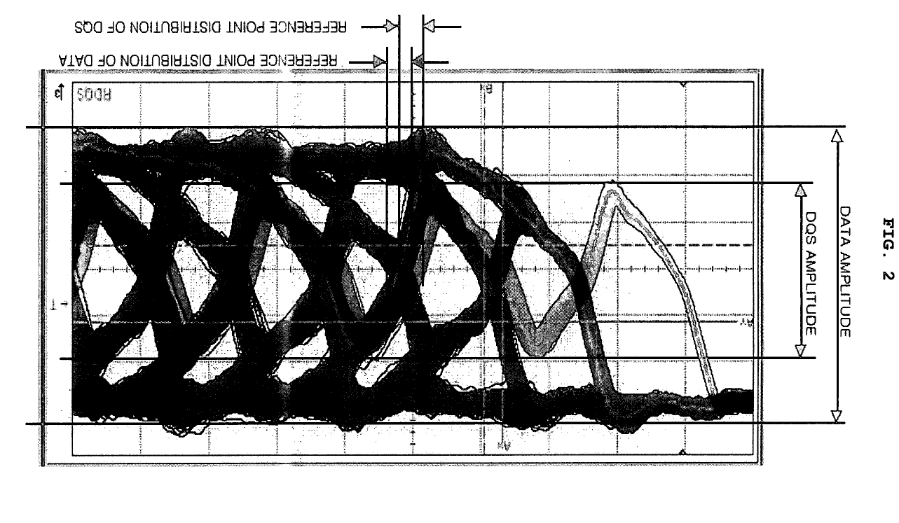

### DESCRIPTION OF EXEMPLARY EMBODIMENTS

Hereinafter, exemplary embodiments of a data output circuit and a data output method of a semiconductor memory apparatus are described with reference to accompanying drawings.

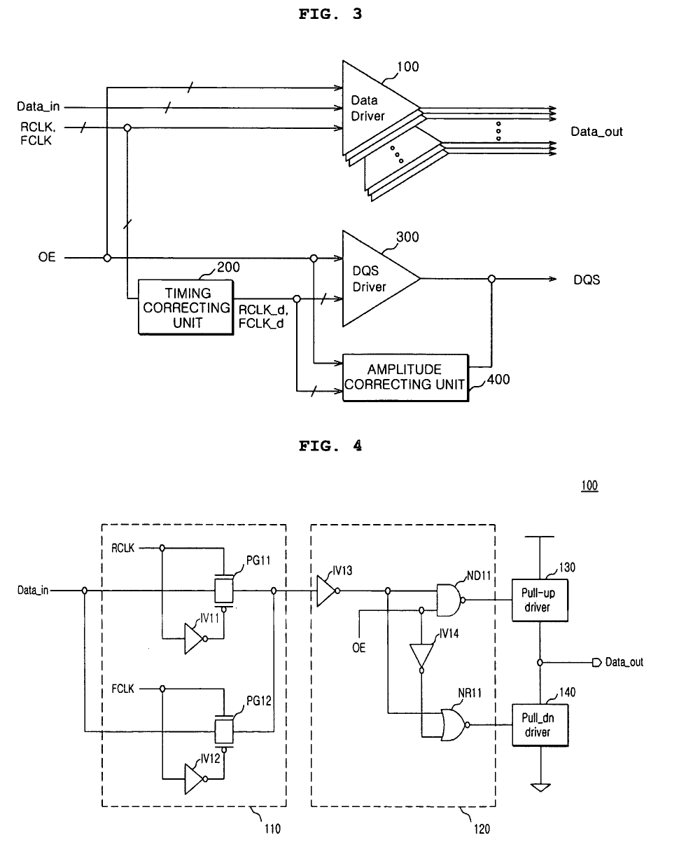

As shown in FIG. 3, a data output circuit of a semiconductor memory apparatus according to an exemplary embodiment includes a plurality of first data drivers 100 that output a plurality of data Data_out based on first control signals RCLK and FCLK. A DQS driver 300 generates and outputs a second control signal DQS synchronized with data output cycles of the data drivers 100 using timing corrected first control signals RCLK_d and FCLK_d. An amplitude correcting unit 400 corrects an amplitude of the second control signal DQS using the timing corrected first control signals RCLK_d and FCLK_d. A timing correcting unit 200 adjusts the timing of the first control signals RCLK and FCLK by a predetermined time to output the timing corrected first control signals. The first control signal RCLK may be designed as a rising clock as known in the art. The first control signal FCLK may be designed as a falling clock as known in the art. The second control signal DQS may be designed as a strobe clock as known in the art.

As shown in FIG. 4, the data driver 100 includes a pull-up driver 130 and a pull-down driver 140 that perform data driving operations based on driving signals. A switching unit 110 passes one of the plurality of data based on the first control signals RCLK and FCLK. A driving unit 120 drives the pull-up driver 130 and the pull-down driver 140 based on an output of the switching unit 110.

The pull-up driver 130 includes a PMOS transistor. The pull-down driver 140 includes an NMOS transistor.

The switching unit 110 includes a first inverter IV11 to which the first control signal RCLK is input, a first pass gate PG11 to which the data Data_in is input through an input terminal, an output of the first inverter IV11 is input through a first control terminal such as a P-Type gate and the first control signal RCLK is input through a second control terminal such as a N-Type gate, a second inverter IV12 to which the first control signal FCLK is input, and a second pass gate PG12 to which the input data Data_in is input through an input terminal, an output of the second inverter IV12 is input through the first control terminal (P-Type gate) and the first control signal FCLK is input through the second control terminal (N-Type gate). An output terminal of the second pass gate PG12 is connected to an output terminal of the first pass gate PG11.

The driving unit 120 includes a third inverter IV13 to which an output of the first gate PG11 of the switching unit 110 is input, a NAND gate ND11 that receives the output of the third inverter IV13 and an output control signal OE to drive the pull-up driver 130, a fourth inverter IV14 to which the output control signal OE is input, and a NOR gate NR11 that receives the output of the third inverter IV13 and the output of the fourth inverter IV14 to drive the pull-down driver 140.

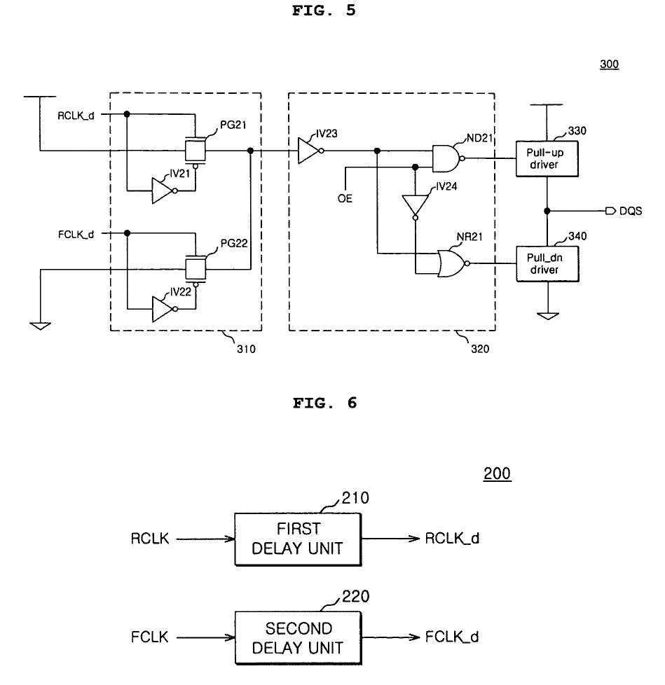

As shown in FIG. 5, the DQS driver 300 includes a pull-up driver 330 and a pull-down driver 340 that perform data driving operations based on driving signals. A switching unit 310 outputs a power supply voltage value or a ground voltage value based on the timing corrected first control signals RCLK_d and FCLK_d. A driving unit 320 drives the pull-up driver 330 and the pull-down driver 340 based on a signal output of the switching unit 310.

The pull-up driver 330 includes a PMOS transistor. The pull-down driver 340 includes an NMOS transistor.

The switching unit 310 includes a first inverter IV21 to which the timing corrected first control signal RCLK_d is input, a first pass gate PG21 to which an output of the first inverter IV21 is input through a first control terminal such as a P-Type gate and the timing corrected first control signal RCLK_d is input through a second control terminal such as a N-Type gate, a second inverter IV22 to which the timing corrected first control signal FCLK_d is input, and a second pass gate PG22 to which the input data Data-in is input through an input terminal, an output of the second inverter IV22 is input through the first control terminal (P-Type gate) and the timing corrected first control signal FCLK_d is input through the second control terminal (N-Type gate). An input terminal of the first pass gate PG21 is connected to a power supply terminal. Further, an input terminal of the second pass gate PG22 is connected to the ground terminal, and an output terminal of the second pass gate PG22 is connected to the first pass gate PG21.

The driving unit 320 includes a third inverter IV23 to which an output of the first gate PG21 of the switching unit 310 is input, a NAND gate ND21 that receives the output of the third inverter IV23 and an output control signal OE to drive the pull-up driver 330, a fourth inverter IV24 to which the output control signal OE is input, and a NOR gate NR21 that receives the output of the third inverter IV23 and the output of the fourth inverter IV24 to drive the pull-down driver 340.

The amplitude correcting unit 400 is configured to reduce the impedance of the DQS driver 300 by operating at the same timing as the DQS driver 300 shown in FIG. 5, and has the same structure as the DQS driver 300. The impedance of the amplitude correcting unit 400 may be varied depending on the impedance to be reduced to be substantially equal to or different from the impedance of the DQS driver 300.

As shown in FIG. 6, the timing correcting unit 200 includes a first delay unit 210 that delays the first control signal RCLK for a first predetermined time to output the timing corrected first control signal RCLK_d, and a second delay unit 220 that delays the first control signal FCLK for a second predetermined time to output the timing controlled control signal FCLK_d. The first and second predetermined time of the first delay unit 210 and the second delay unit 220 may be substantially equal to one another or the first and second predetermined time may be determined by simulation.

The operation of the semiconductor memory apparatus according to an exemplary embodiment is described below.

The switching unit 110 of the data driver 100 outputs the input data Data_in, that is sequentially input according to a cycle, to the driving unit 120 based on the first control signals RCLK and FCLK.

More specifically, during a period when the first control signal RCLK is at a high level, the first pass gate PG11 is turned on to output the input data Data_in. During a period when the first control signal FCLK is at a high level, the second pass gate PG12 is turned on to output the input data Data_in.

When the output control signal OE is enabled to be at a high level, the driving unit 120 drives the pull-up driver 130 or the pull-down driver 140 based on the output of the switching unit 110.

More specifically, during a period when the input data Data_in is at a high level, the input data Data_in is changed to a low level through the third inverter IV13 and input to the first terminals of the NAND gate ND11 and the NOR gate NR11. During a period when the output control signal OE is at a high level, the high level signal is input to the second input terminal of the NAND gate ND11. The low level signal is input to the second input terminal of the NOR gate NR11. Accordingly, during a period when the output control signal OE is at a high level, the NAND gate ND11 outputs the high level signal to the pull-up driver 130, and the NOR gate NR11 outputs the high level signal to the pull-down driver 140.

During a period when the input data Data_in is at a low level, the input data Data_in is changed by the third inverter IV13 to be at a high level and is input to the first input terminals of the NAND gate ND11 and the NOR gate NR11, respectively. During a period when the output control signal OE is at a high level, the high level signal is input to the input second terminal of the NAND gate ND11. The low level signal is input to the second input terminal of the NOR gate NR11. Accordingly, during a period when the output control signal OE is at a high level, the NAND gate ND11 outputs the high level signal to the pull-up driver 130, and the NOR gate NR11 outputs the high level signal to the pull-down driver 140.

As a result, the pull-up driver 130 or the pull-down driver 140 performs a pull-up operation or a pull-down operation to output the output data Data_out.

Further, the first delay unit 210 and the second delay unit 220 of the timing correcting unit 200 delay the first control signals RCLK and FCLK for a predetermined amount of time to output the timing corrected first control signals RCLK_d and FCLK_d.

Therefore, the switching unit 310 of the DQS driver 300 outputs the power supply level signal and the ground level signal to the driving unit 320 based on the timing corrected first control signals RCLK_d and FCLK_d.

More specifically, during a period when the timing corrected first control signal RCLK_d is at a high level, the first pass gate PG21 is turned on to output the power supply voltage (high level) signal. During a period when the timing corrected first control signal FCLK_d is at a high level, the second pass gate PG22 is turned on to output the ground voltage (low level) signal.

During a period when the output control signal OE is enabled to be at a high level, the driving unit 320 drives the pull-up driver 330 or the pull-down driver 340 based on the output of the switching unit 310.

More specifically, the power supply voltage is changed into a low level by the third inverter IV23 to be input to the first input terminals of the NAND gate ND21 and the NOR gate NR21. During a period when the output control signal OE is at a high level, the high level signal is input to the second terminal of the NAND gate ND21. The low level signal is input to the second input terminal of the NOR gate NR21. Accordingly, during a period when the output control signal OE is at a high level, the NAND gate ND21 outputs the high level signal to the pull-up driver 330, and the NOR gate NR21 outputs the high level signal to the pull-down driver 340.

The ground voltage is changed into a high level by the third inverter IV23 and is input to the first input terminals of the NAND gate ND21 and the NOR gate NR21. During a period when the output control signal OE is at a high level, the high level signal is input to the second input terminal of the NAND gate ND21. The low level signal is input to the second input terminal of the NOR gate NR21. Accordingly, during a period when the output control signal OE is at a high level, the NAND gate ND21 outputs the low level signal to the pull-up driver 330, and the NOR gate NR21 outputs the low level signal to the pull-down driver 340.

As a result, the pull-up driver 330 or the pull-down driver 340 performs a pull-up operation or a pull-down operation to output the second control signal DQS.

The amplitude correcting unit 400 outputs the same signal as the DQS driver 300 through the output terminal of the DQS driver 300 based on the timing corrected first control signals RCLK_d and FCLK_d during a period when the output control signal OE is enabled.

More specifically, while the DQS driver 300 outputs the second control signal DQS, the amplitude correcting unit 400 performs the same output operation through the same output terminal as the DQS driver 300. The output impedance of the DQS driver 300 is reduced due to the operation of the amplitude correcting unit 400.

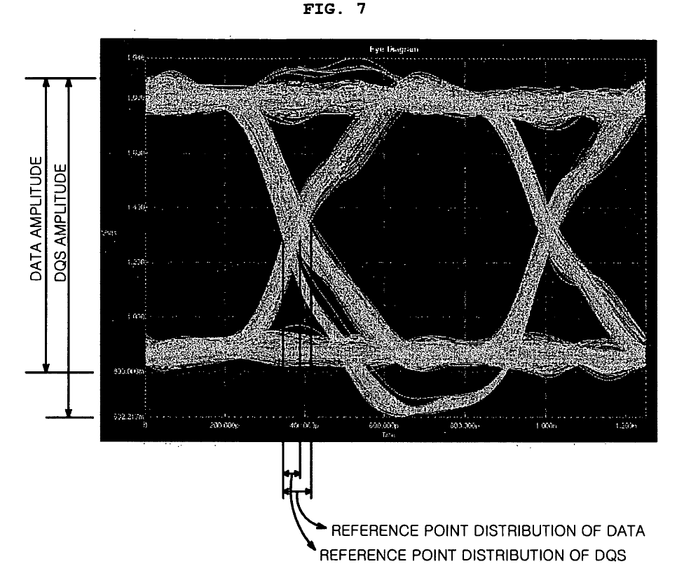

As shown in FIG. 7, the amplitude of the second control signal DQS is increased as compared with the related art due to the reduced output impedance of the DQS driver 300, and thus the distribution of the reference points matches to the output data Data_out. Therefore, the output data Data_out and the skew of DQS are substantially minimized.

For example, the amplitude of the second control signal DQS is increased by using the amplitude correcting unit 400, and thus the timing of the second control signal DQS may be made faster than the output data Data_out.

The timing correcting unit 200 may make the DQS driver 300 and the amplitude correcting unit 400 to operate at a timing later than the timing of the data driver 100.

As described above, the delayed time of the timing correcting unit 200 is set to match to the timing of the output data Data_out and the second control signal DQS by the simulation of the circuit structure including the amplitude correcting unit 400.

It will be apparent to those skilled in the art that various modifications and changes may be made without departing from the scope and spirit of the described. Therefore, it should be understood that the above exemplary embodiments are not limiting, but illustrative in all aspects. The scope of the application is defined by the appended claims rather than by the description preceding them, and therefore all changes and modifications that fall within metes and bounds of the claims, or equivalents of such metes and bounds are therefore intended to be embraced by the claims.

According to the data output circuit of semiconductor memory apparatus according to an exemplary embodiment, since the operation timing of the DQS driver is controlled and the impedance is reduced to minimize the amplitude difference and the skew of the output data Data_out and control signal DQS, it is possible to improve the performance of the entire system by increasing an input margin of a system to which data output from the semiconductor memory is input.

Further, it is possible to expand the applicable range of the product because the semiconductor memory apparatus can be applied to a high speed system by minimizing a difference in the amplitude and the skew.

What is claimed is:

1. A data output circuit for a semiconductor memory apparatus, comprising:
a plurality of first data drivers to output a plurality of data based on first control signals;
a second driver to generate and output to outside of the semiconductor memory apparatus a second control signal having an amplitude and synchronized with data output cycles of the first data drivers based at least on the first control signals; and
an amplitude correcting unit to correct an amplitude of the second control signal based at least on the first control signals.

2. The data output circuit of claim 1, wherein the first control signals include:
a first clock having a first phase; and
a second clock having a second phase that is inverted with respect to the first clock.

3. The data output circuit of claim 1, wherein each first data driver includes:
a pull-up driver and a pull-down driver to drive data based on driving signals;
a switching unit to pass as output one of the plurality of data based on the first control signals; and
a driving unit to drive the pull-up driver and the pull-down driver based at least on the output of the switching unit.

4. The data output circuit of claim 3, wherein the switching unit includes:
a first switch having an input terminal to which one of the plurality of data is input, a control terminal to which the first clock is input through, and an output terminal; and
a second switch having a control terminal to which the second clock is input, an input terminal coupled to the input terminal of the first switch, and an output terminal coupled to the output terminal of the first switch.

5. The data output circuit of claim 3, wherein the driving unit includes:
a first logic circuit to receive the output of the switching unit and drive the pull-up driver based at least on an output control signal; and
a second logic circuit to receive the output of the switching unit and drive the pull-down driver based at least on the output control signal.

6. The data output circuit of claim 1, wherein the second driver includes:
a pull-up driver and a pull-down driver to drive the second control signal based on a driving signal;
a switching unit to output one of a power supply voltage value or a ground voltage value based on the first control signals; and
a driving unit to drive the pull-up driver and pull-down driver based at least on the output of the switching unit.

7. The data output circuit of claim 6, wherein the switching unit includes:
a first switch having an input terminal to which the power supply voltage is input, a control terminal to which a delayed first clock, and an output terminal; and
a second switch having an input terminal to which a ground voltage, a control terminal to which a delayed second clock is input, and, an output terminal coupled to the output terminal of the first switch.

8. The data output circuit of claim 6, wherein the driving unit includes:
a first logic circuit to receive the output of the switching unit and drive the pull-up driver based at least on an output control signal; and
a second logic circuit to receive the output of the switching unit and drive the pull-down driver based at least on the output control signal.

9. The data output circuit of claim 1, wherein the amplitude correcting unit and the second driver have output terminals is coupled to each other.

10. The data output circuit of claim 1, wherein the amplitude correcting unit includes:
a pull-up driver and a pull-down driver to drive a signal level of the output of the second driver based at least on a driving signal;
a switching unit to output a power supply voltage value or a ground voltage value based on the first control signals; and
a driving unit to drive the pull-up driver and the pull-down driver based at least on the output of the switching unit.

11. The data output circuit of claim 10, wherein the switching unit includes:
a first switch having an input terminal to which the power supply voltage is input, a control terminal to which a delayed first clock is input, and an output terminal; and
a second switch having an input terminal to which the ground voltage is input, a control terminal to which a delayed second clock is input, and an output terminal coupled to the output terminal of the first switch.

12. The data output circuit of claim 10, wherein the driving unit includes:
a first logic circuit to receive the output of the switching unit and drive the pull-up driver based at least on an output control signal; and
a second logic circuit to receive the output of the switching unit and drive the pull-down driver based at least on the output control signal.

13. The data output circuit of claim 12, wherein the first logic circuit includes:
an inverter to which the output of the switching unit is input to produce an output; and
a NAND gate to which the output of the inverter and the output control signal are input.

14. The data output circuit of claim 12, wherein the second logic circuit includes:
an inverter to which the output of the switching unit is input to produce an output; and
a NOR gate to which an inverted output of the switching unit and the output of the inverter are input.

15. A data output circuit for a semiconductor memory apparatus, comprising:
a plurality of first drivers to output a plurality of data based on first control signals;
a timing correcting unit to modify timing of the first control signals by a predetermined time and output first and second timing corrected control signals;
a second driver to generate and output to outside of the semiconductor memory apparatus a second control signal having an amplitude and synchronized with data output cycles of the first drivers based on the first and second timing corrected control signals; and
an amplitude correcting unit to correct an amplitude of the second control signal based on the first and second timing corrected control signals.

16. The data output circuit of claim 15, wherein the first control signals include:
a first clock having a first phase; and
a second clock having a second phase that is inverted with respect to the first clock.

17. The data output circuit of claim 15, wherein each first driver includes:
a pull-up driver and a pull-down driver to drive data based on driving signals;
a switching unit to pass as output one of the plurality of data based on the first control signals; and
a driving unit to drive the pull-up driver and the pull-down driver based on the output of the switching unit.

18. The data output circuit of claim 17, wherein the switching unit includes:
a first switch having an input terminal to which one of the plurality of data is input, a control terminal to which the first clock is input through, and an output terminal; and
a second switch having a control terminal to which the second clock is input, an input terminal coupled to the input terminal of the first switch, and an output terminal coupled to the output terminal of the first switch.

19. The data output circuit of claim 17, wherein the driving unit includes:
a first logic circuit to receive the output of the switching unit and drive the pull-up driver based at least on an output control signal; and
a second logic circuit to receive the output of the switching unit and drive the pull-down driver based at least on the output control signal.

20. The data output circuit of claim 15, wherein the second driver includes:
a pull-up driver and a pull-down driver to drive the second control signal based on a driving signal;
a switching unit to output a power supply voltage value or a ground voltage value based on the first and second timing corrected control signals; and
a driving unit to drive the pull-up driver and pull-down driver based on the output of the switching unit.

21. The data output circuit of claim 20, wherein the switching unit includes:
a first switch having an input terminal to which the power supply voltage is input, a control terminal to which the first timing corrected control signal is input, and an output terminal; and
a second switch having an input terminal to which the ground voltage is input, a control terminal to which the second timing corrected control signal is input, an output terminal coupled to the output terminal of the first switch.

22. The data output circuit of claim 20, wherein the second driving unit includes:
a pull-up driver and a pull-down driver to drive a second control signal based on at least a driving signal;
a switching unit to output a power supply level or a ground level based on at least the timing corrected first control signal; and
a driving unit to drive the pull-up driver and pull-down driver based on at least the output of the switching unit.

23. The data output circuit of claim 15, wherein amplitude correcting unit and the second driver have output terminals coupled to each other.

24. The data output circuit of claim 15, wherein the amplitude correcting unit includes:
a pull-up driver and a pull-down driver to drive a signal level of the output of the second driver based on a driving signal;
a switching unit to output one of a power supply voltage value or a ground voltage value based at least on the first and second timing corrected control signals; and
a driving unit to drive the pull-up driver and the pull-down driver based at least on the output of the switching unit.

25. The data output circuit of claim 24, wherein the switching unit includes:
a first switch having an input terminal to which the power supply voltage is input, a control terminal to which the first timing corrected control signal is input, and an output terminal; and
a second switch having an input terminal to which the ground voltage is input, a control terminal to which the second timing corrected control signal is input, and an output terminal coupled to the output terminal of the first switch.

26. The data output circuit of claim 24, wherein the driving unit includes:
a first logic circuit to receive the output of the switching unit and drive the pull-up driver based at least on an output control signal; and
a second logic circuit to receive the output of the switching unit and drive the pull-down driver based at least on the output control signal.

27. The data output circuit of claim 26, wherein the first logic circuit includes:
an inverter to which the output of the switching unit is input to produce an output; and
a NAND gate to which the output of the inverter and the output control signal are input.

28. The data output circuit of claim 26, wherein the second logic circuit includes:
an inverter to which the output of the switching unit is input; and
a NOR gate to which an inverted output of the switching unit and the output of the inverter are input.

29. The data output circuit of claim 15, wherein the timing correcting unit includes a delay unit that delays each first control signal for a predetermined time.
